(19) United States
(12) Patent Application Publication
(10) Pub. No.: US 2011/0312120 A1
(43) Pub. Date: Dec. 22, 2011

(54) ABSORBER REPAIR IN SUBSTRATE FABRICATED PHOTOVOLTAICS

(75) Inventors: Kurt H. Weiner, San Jose, CA (US); Gaurav Verma, Sunnyvale, CA (US)

(73) Assignee: REEL SOLAR, INC., San Jose, CA (US)

(21) Appl. No.: 13/151,113

(22) Filed: Jun. 1, 2011

Related U.S. Application Data
(60) Provisional application No. 61/357,456, filed on Jun. 22, 2010.

(51) Int. Cl. H01L 31/18

(52) U.S. Cl. 438/64; 257/E31.032

(57) ABSTRACT

The invention relates generally to methods of repairing defects in thin films. Void defects in thin films are repaired using methods that take advantage of substrate manufacturing protocols rather than conventional superstrate manufacturing protocols. Methods described herein are simple, robust and compatible with existing processes and equipment used in the manufacture of superstrate devices.

### CROSS-REFERENCE TO RELATED APPLICATIONS

This application claims benefit under 35 U.S.C. §119(e) of U.S. Provisional Patent Application No. 61/357,456, filed Jun. 22, 2010, naming Kurt H. Weiner and Gaurav Verma as inventors. U.S. Provisional Patent Application No. 61/357,456 is incorporated herein by reference in its entirety and for all purposes.

### FIELD

The invention relates generally to methods of addressing layer defects in electronic stack devices such as photovoltaic and/or electrochromic stacks where voids in an intervening layer would otherwise cause electronic shorts between two electrode or contact layers. Methods described herein find particular use in solar cell fabrication.

### BACKGROUND

Solar or photovoltaic cells are devices that convert photons into electricity by the photovoltaic effect. Solar cells are assembled together to make solar panels, solar modules, or photovoltaic arrays. Thin film solar cells are stacked structures, having layers of materials, including photovoltaic materials, typically stacked on a superstrate, substrate or sandwiched between a superstrate and a substrate. There are many fabrication techniques used for fabricating the individual layers of the stack.

Manufacturing of thin film photovoltaic (PV) devices promises coal-competitive normalized cost of electricity due to the efficient use of photovoltaic materials, process simplicity and high conversion efficiencies that can be recognized using the technology. However, to reach cost parity with coal-fired electricity, thin film PV must produce devices at very large scale with very high yield and very high performance. One of the key manufacturing challenges is the ability to produce defect-free films over areas that span multiple square meters. When attempting manufacturing on this scale, it is difficult to cost-effectively achieve the requisite level of process control and uniformity to ensure a defect-free layer.

One particularly troublesome defect in films is a void, or hole in the film. Though these voids or “pinholes” are small, electronic devices that utilize material layers in a stack, such as electrochromic and/or photovoltaic devices, can suffer from poor performance due to voids in intervening layers between electrodes because the voids allow electrical shorts across electrode layers in the device. These voids, for example due to processing stresses and/or limitations, effect the ultimate performance of the device, because there is a leakage current associated with the electrodes or contacts being in direct electrical contact due to the short across the void defect, for example, because the void contains material from later formed conductive layers. For example a photovoltaic device will generate less power or be inoperable, or, for example, an electrochromic device will have inefficient transitions, causing bright spots or making the device inoperable. With regard to photovoltaic stack devices, conventional void defect repair methods exist for superstrate fabrication protocols, but there remains a need for void defect repair in substrate fabrication methods.

What is needed, therefore, are methods that allow for effective and relatively low cost repair of void defects produced in large area thin films. Given the demand for renewable energy, improved methods are particularly important for solar cell fabrication. In particular, what is needed are methods of void defect repair when substrate fabrication methods are employed.

### SUMMARY

The invention relates generally to methods of repairing defects in thin films. Void defects in thin films are repaired using methods that take advantage of substrate manufacturing protocols rather than conventional superstrate manufacturing protocols. Methods described herein are simple, robust and compatible with existing processes and equipment used in the manufacture of superstrate devices.

One embodiment is a method of fabricating a photovoltaic device, including: (a) forming an absorber layer on a back contact layer; (b) filling voids, at least partially, in the absorber layer with an electrically insulating material; and (c) forming a window layer on the absorber layer. In one embodiment, filling voids, at least partially, in the absorber layer with an electrically insulating material includes: (i) applying the electrically insulating material to the absorber layer to fill voids while leaving an excess of the electrically insulating material on the field region of the absorber layer; and (ii) removing the excess of the electrically insulating material from the field region of the absorber layer to expose the field region of the absorber layer while leaving at least some of the electrically insulating material in the voids. Photoresists work well in this context because of their ability to be tailored to specific process demands, for example, selective exposing of photoresists using a mask. Both positive and negative photoresists find use in particular embodiments described herein. In embodiments of the invention, the absorber layer and/or the back contact are used as exposure masks when the electrically insulating material is a photoresist.

Methods of the invention address substrate fabrication protocols, where an opaque back contact layer resides on either an opaque substrate or a transparent substrate. When an opaque substrate is used, the electrically insulating material is applied to the voids and any excess remaining on the field region is removed. The electrically insulating material may or may not be a photoresist. The excess material is removed, for example, via etch back and/or an expose and develop process in order to dissolve away unexposed material, for example, when the insulator is a photoresist. In one embodiment, a positive photoresist is employed with off-axis illumination in order to selectively expose the photoresist in the field region and possibly a small portion in an upper region of each void. A developer is used to remove the exposed photoresist from the field region and possibly some of the resist in the upper region of the voids and/or etch back is used. When a transparent substrate is used, the absorber layer, along with the void defects, serves as an etch mask where the voids are extended, via etching, through the back contact so that the transparent substrate is exposed at the bottom of the voids. After application of, for example, a negative photoresist, the opaque back contact acts as a mask when illumination is applied through the transparent substrate. In this way, the photoresist in the voids is selectively exposed, so that a developer can be used to remove the photoresist from the field region of the absorber layer while leaving photoresist in the voids. Unexposed portions of the photoresist can also be removed via etch back.

In one embodiment, the absorber layer is CIGS, CdTe or amorphous silicon. Window layers include at least one of CdS, ZnSe, ZnS, ZnO, Cd(OH)SH, In(OH)SH, SnO₂ and Sn(O₂)S₂. In one embodiment, the absorber layer is CdTe and the window layer is CdS.

In one embodiment, after the absorber layer is repaired, a front contact layer is formed over the window layer; and the photovoltaic stack is encapsulated so as to form a solar cell module.

Particular aspects of methods are described in more detail below.

### BRIEF DESCRIPTION OF THE DRAWINGS

FIG. 1 is a cross-sectional depiction of a solar cell photovoltaic stack structure.

FIG. 2 is a cross-sectional depiction of conventional superstrate photovoltaic stack formation.

FIG. 3 is a cross-sectional depiction of a substrate solar cell photovoltaic stack formation.

FIGS. 4A and 4B are process flows in accord with methods described herein.

FIGS. 5A-5D are cross-sectional depictions in accord with fabrication methods described herein.

FIGS. 6A-6E are cross-sectional depictions in accord with fabrication methods described herein.

### DETAILED DESCRIPTION

### A. Solar Cell Structure

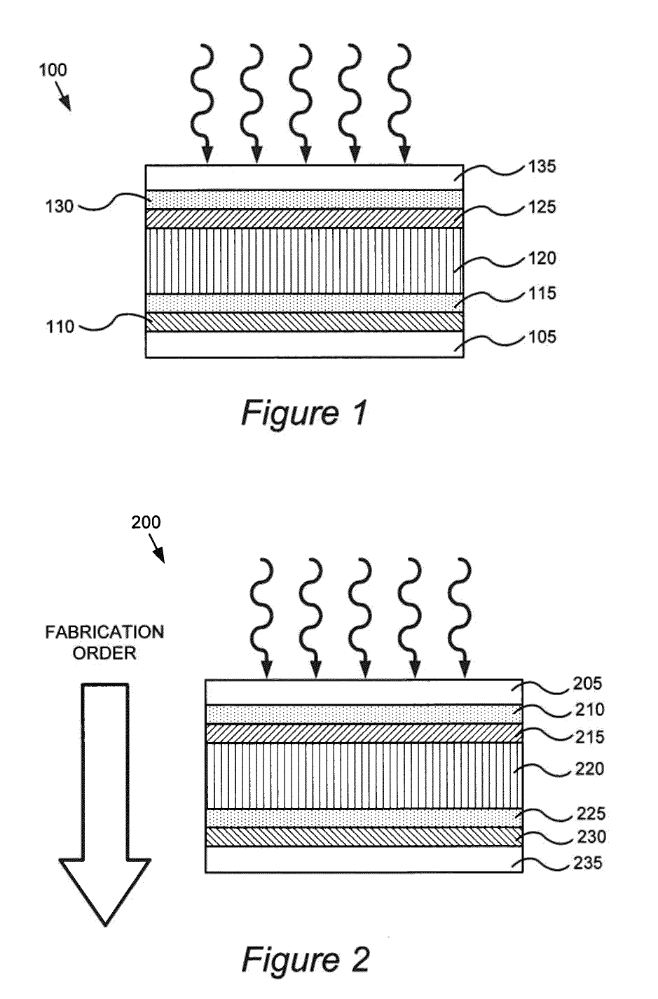

FIG. 1 depicts a simplified diagrammatic cross-sectional view of a typical thin film solar cell, 100. As illustrated, thin film solar cells typically include the following components: back encapsulation, 105, substrate, 110, a back contact layer, 115, an absorber layer, 120, a window layer, 125, a top contact layer, 130, and top encapsulation layer, 135.

Back encapsulation can generally serve to provide encapsulation for the cell and provide mechanical support. Back encapsulation can be made of many different materials that provide sufficient sealing, moisture protection, adequate mechanical support, ease of fabrication, handling and the like. In many thin film solar cell implementations, back encapsulation is formed from glass although other suitable materials may be used.

A substrate layer can also be used to provide mechanical support for the fabrication of the solar cell. The substrate can also provide electrical connectivity. In many thin film solar cells, the substrate and back encapsulation are the same. Glass plate is commonly used in such instances, although opaque substrates are also commonly used since light need not pass through this side of the photovoltaic stack.

A back contact layer can be formed from a thin film of material that provides one of the contacts to the solar cell. Typically, the material for the back contact layer is chosen such that the contact resistance for the electrons/holes flowing from/to the absorber layer is minimized. This result can be achieved by fabricating an ohmic or a tunneling back contact layer. This back contact layer can be formed from many different materials depending on the type of thin film solar cell. For example, in copper indium gallium diselenide (CIGS) solar cells, this layer can be molybdenum. In cadmium telluride (CdTe) thin film solar cells, this back contact layer can be made, for example, of nickel or copper or graphite. These materials are merely illustrative examples. That is, the material composition of the back contact layer is dependent on the type of absorber material used in the cell. The thickness of a back contact layer film is typically in the range of a few microns.

The absorber layer is a thin film material that generally absorbs the incident photons (indicated in FIG. 1 by the squiggly lines) and converts the photons to electrons. This absorber material is typically semiconducting and can be a p-type or an n-type semiconductor. An absorber layer can be formed from, for example, CIGS, CdTe or amorphous silicon. The thickness of the absorber layer depends on the semiconducting material, and is typically of the order of microns, varying from a few microns to tens of microns.

A window layer is also typically a thin film of semiconducting material that creates a p-n junction with the absorber layers and, in addition, allows the maximum number of photons in the energy regime of interest to pass through to the absorber layer. The window layer can be an n- or p-type semiconductor, depending on the material used for the absorber layer. For example, the window layer can be formed from a cadmium sulphide (CdS) n-type semiconductor for CdTe and CIGS thin film solar cells. The typical thickness of this layer is of the order of hundreds to thousands of angstroms.

A top contact is typically a thin film of material that provides one of the contacts to the solar cell. The top contact is made of a material that is transparent to the photons in the energy regime of interest for the solar cell. This top contact layer is typically a transparent conducting oxide (TCO). For CdTe, CIGS, and amorphous silicon thin film solar cells, the top contact can be formed from, for example, indium tin oxide (ITO), aluminum doped zinc oxide (ZnO) or fluorine doped tin oxide (SnO₂). The top contact layer thickness can be of the order of thousands of angstroms.

A top encapsulation layer can be used to provide environmental protection and mechanical support to the cell. The top encapsulation is formed from a material that is highly transparent in the photon energy regime of interest. This top encapsulation layer can be formed from, for example, glass. In this respect, a glass encapsulation serves also as a superstrate for structural support.

Thin film solar cells are typically connected in series, in parallel, or both, depending on the needs of the end user, to fabricate a solar module or panel. The solar cells are connected to achieve the desired voltage and current characteristics for the panel. The number of cells connected together to fabricate the panel depends on the open circuit voltage, short circuit current of the cells, and on the desired voltage and current output of the panel. The interconnect scheme can be implemented, for example, by laser scribing for isolation and interconnection during the process of the cell fabrication. Once these panels are made, additional components such as bi-pass diodes, rectifiers, connectors, cables, support structures etc. are attached to the panels to install them in the field to generate electricity. The installations can be, for example, in households, large commercial building installations, large utility scale solar electricity generation farms and in space, for example, to power satellites and space craft.

### B. Superstrate Solar Cell Fabrication

Solar cell photovoltaic stacks are conventionally constructed in an order starting from, for example, a top encapsulation layer, a top contact layer, a window layer, an absorber layer, a back contact layer and so on, that is, in an order opposite of the description of the layers with reference to FIG. 1. The top encapsulation layer is a superstrate upon which the photovoltaic stack is built. For example the top encapsulation layer can be glass, a superstrate upon which subsequent layers are formed.

FIG. 2 shows a diagrammatic illustration of conventional photovoltaic stack formation, that is a superstrate fabrication protocol. This example is described in terms of CdS-based window layers and CdTe-based absorber layers, but solar cells can have a wide variety of window and absorber layer materials so long as they are compatible with one another. The process starts with the top encapsulation layer, and the cell stack is built by subsequent depositions of top contact layer, window layer, absorber layer, etc. Other layers may be formed in addition to the described layers and formation of some of the described layers is optional, depending on the desired cell stack structure.

Referring again to FIG. 2, a top encapsulation layer, 205, and top contact layer, 210, can be initially cleaned, dried, cut to size, and edge seamed. Commonly, the top encapsulation and top contact layer are in the form of a glass superstrate (encapsulation layer) coated with a transparent conductive oxide (top contact). Float glass with transparent conductive oxide coatings, for example indium tin oxide, doped zinc oxide or doped tin oxide, are commercially available from a variety of venders, for example, glasses sold under the trademark TEC Glass™ by Pilkington of Toledo, Ohio, and SUNGATE™ 300 and SUNGATE™ 500 by PPG Industries of Pittsburgh, Pa. TEC Glass™ is a glass coated with a fluorinated tin oxide conductive layer. A wide variety of solvents, for example deionized water, alcohols, detergents and the like, can be used for cleaning the glass. As well there are many commercially available industrial-scale glass washing apparatus appropriate for cleaning large substrates, for example, Lisec™ (a trade name for a glass washing apparatus and process available from (LISEC Maschinenbau Gmbh of Seitenstetten, Austria).

Once the TCO coated glass is cleaned, a CdS layer, 215, is then deposited, for example, by using an aqueous solution of, for example, a cadmium salt and elemental sulphur or sulphur containing compound composition. The solution does not have to be aqueous. That is, other solvents, such as dimethylsulfoxide (DMSO), can be used. This deposition can be done using electrodeposition. For electrodeposition, the ITO coating on the glass can form one of the electrodes. The other electrode can be, for example, made of graphite, and the electrolyte can be, for example, a DMSO solution of a cadmium salt and elemental sulfur. Potential is applied between the electrodes so that CdS is deposited from the solution onto the ITO coated glass substrate. Another method of depositing the CdS layer is chemical deposition, for example via wet chemistry or dry application such as CVD. The CdS deposited is an n-type semiconductor and its thickness is typically between 500 Å and 1 μm. Subsequent to the deposition, the layer can be annealed, for example under an inert atmosphere such as argon, to achieve film densification and grain growth to improve the electrical and mechanical properties of the CdS film.

For illustration purposes, electrodeposition of CdS is sometimes described herein as being used in the fabrication of window layers for CdTe-based solar cells. However, window layers can include materials other than CdS, and electrodeposition is not the only method of depositing CdS, that is, the invention is not limited to this particular chemistry or application technique.

Cadmium sulphide (CdS) is an important semiconductor, and finds particular use as a window layer and n-type semiconductor in, for example, cadmium telluride (CdTe), copper indium gallium diselenide (CIGS), cadmium selenium telluride (CdSeₓTe₁₋ₓ), and the like for solar cell manufacturing. In these exemplary solar cells, CdS can serve two purposes, as an n-type semiconductor for forming the p-n junction with the absorber layer and as a window layer to allow photons to pass through to the absorber layer.

The nanostructure of CdS can be tailored to influence such a window layer's band gap. Band gap has a direct influence on the amount of light the window layer allows to pass through to the absorber layer. For example, a smaller grain size increases the band gap of the semiconductor which allows more light to pass through the window layer. Methods described herein allow for taking full advantage of processing CdS films for smaller grain size and increased band gap.

A cadmium telluride layer, 220, is then, for example, electrochemically deposited on the CdS/TCO/Glass stack (now a substrate for electrodeposition), for example, from an acidic or basic media containing a cadmium salt and tellurium oxide. In this process, the CdS/TCO/Glass substrate forms one of the electrodes and platinum or other materials can be used as the other electrode. The electrolyte can contain an acidic or basic media, in solvents such as water, DMSO or other solvents, with a cadmium salt and tellurium oxide, for example. Films of thickness ranging from 1 to 10 gm are typically deposited. Cadmium telluride films may then be annealed at approximately 400° C. in an air or oxygen or CdCl₂ environment so as to improve the electrical properties of the film and also to convert the CdTe film to a p-type semiconductor. It is believed that these methods optimize grain size and thus improve the electrical properties of the films.

After this CdTe deposition and annealing, a laser scribing process is typically performed to remove CdS and CdTe from specific regions (not shown). In this scribing operation, the laser scribing is utilized such that CdS and CdTe are removed from specific regions of the solar panel. However, the conductive oxide (e.g., Al doped ZnO or ITO) is not removed by the laser scribe. Then a second laser scribing step is performed in which CdS, CdTe and TCO are removed from specified regions.

A back contact layer, 225, can then be deposited on the CdTe layer, using for example sputtering or electrodeposition. For example, copper, nickel, graphite and/or other metals, alloys and composites can be used for the back contact layer. This back contact fabrication step can be followed by an anneal, for example, at temperatures of between about 150° and about 200° C. to form an ohmic contact. The back contact layer can cover the CdTe layer and also fill the vias (not shown) created in the CdTe/CdS layer by the laser scribing process.

After back contact layer deposition and annealing, laser scribing can typically be used to remove the back contact layer material from specific areas, but the CdTe layer is not etched away in this process. This removal step can complete the process for isolation and interconnecting the solar cells in series in the solar panel/module.

After the deposition of the back contact layer, an encapsulation layer, 230, can be applied, for example, using ethylvinyl acetate (EVA). Encapsulation protects the photovoltaic stack. Glass, 235, can be added for further structural support (and protection) of the stack.

The above described superstrate fabrication protocol represents a brief outline and many variants of this process can be employed for the fabrication of CdTe thin film solar cells. For other types of thin film solar cells, different chemicals, etc. can be employed. In this description, example process steps have been described for illustrative purposes. Other steps would typically include additional details of the laser scribing and ablation steps employed for the fabrication of the interconnect schemes and cell isolations, multiple clean and drying steps between the different layer depositions and the like. Values for the layer thicknesses, anneal temperatures, chemical composition etc. described herein are merely illustrative, and can vary across a wide range as processes are optimized for many different output variables.

### C. Substrate Solar Cell Fabrication

In conventional superstrate fabrication protocols for solar cells, for example as outlined above in relation to FIG. 2, the window layer is deposited before the deposition of the absorber layer and formation of the back ohmic contact. The absorber layer typically requires processing, such as a relatively high temperature thermal anneal, to improve its photovoltaic properties. For example, a CdTe layer can be annealed in cadmium chloride to passivate its grain boundaries and to convert it to a p-type semiconductor. Anneals can also be utilized to optimize the grain structure of the absorber layer. These anneals can range from about 200° C. to about 650° C. The formation of the ohmic back contact layer also requires an optimization process, such as an anneal, for example at temperatures between about 100° C. and about 300° C. The anneals for improving absorber layer characteristics and for the formation of the back contact negatively impacts the grain structure of the window layer, for example increasing the grain size of the window layer and decreasing the band gap, which decreases the transmission properties of the window layer. Thus in the superstrate integration scheme, the properties of the window layer can not be controlled independently of the process parameters of the absorber layer and the back contact. As a result, superstrate fabrication protocols lead to degradation of the properties of the window layer and thus lower performance solar cells.

By inverting the photovoltaic stack formation order, that is, using substrate fabrication protocols, independent control of fabrication conditions for the back contact, absorber layer and window layer is achieved. For example, methods of improving the window layer's properties by decoupling the formation parameters of the window layer from those of the absorber layer and/or back contact layer, are described in U.S. patent application Ser. No. 12/764,812, filed Apr. 21, 2010, naming as inventors Kurt Weiner, et al., and entitled, “Methods for Integrating Quantum Window Structures into Solar Cells”, which is incorporated by reference herein for all purposes. The general procedure for substrate photovoltaic stack formation is described below.

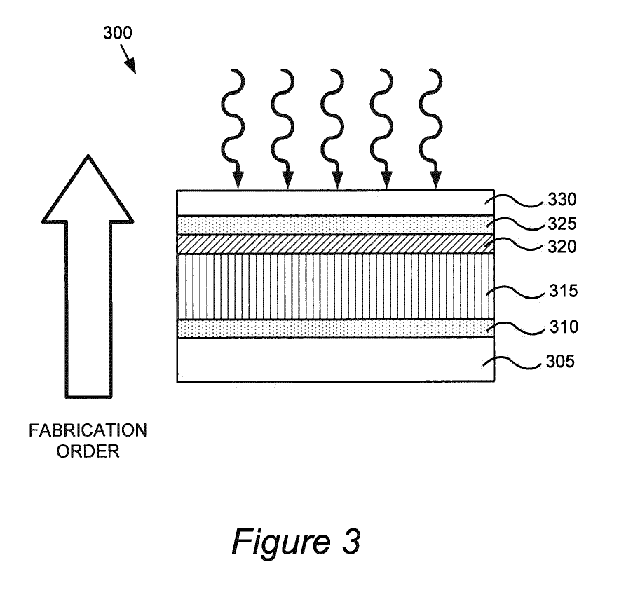

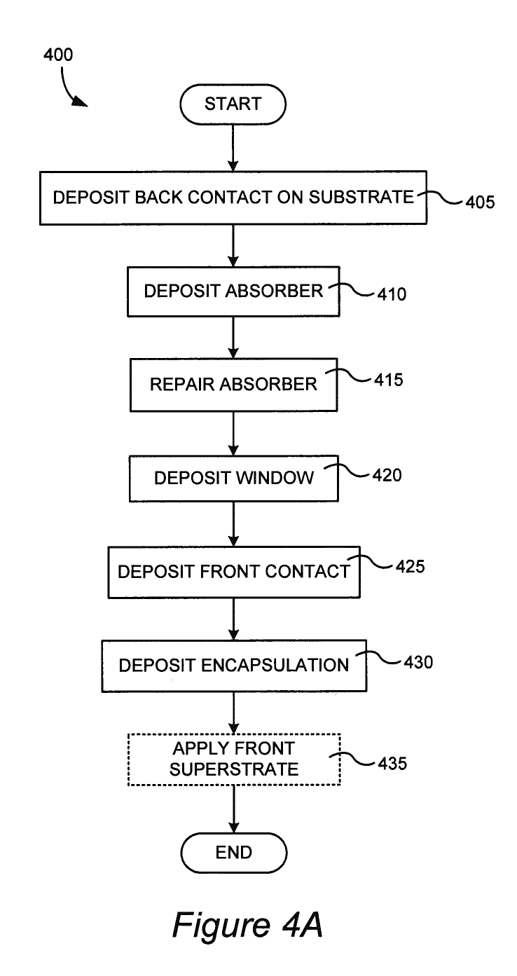

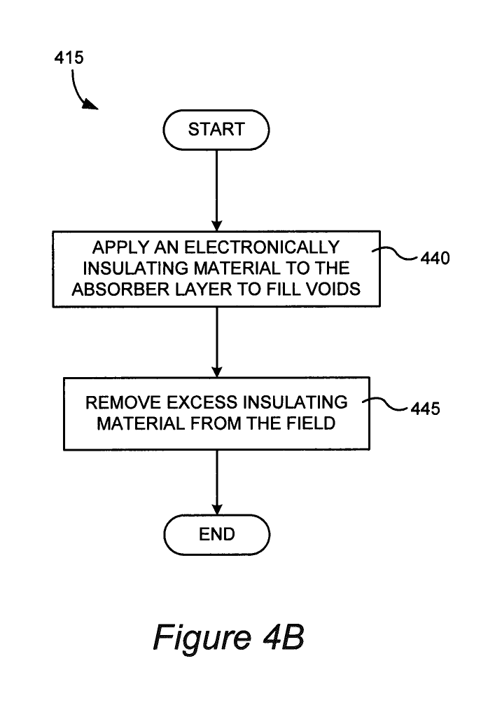

FIG. 3 illustrates a cross-section, 300, of a photovoltaic stack fabricated according to substrate protocols, that is, starting from a (back) substrate and forming thin films thereon successively to form a photovoltaic stack. FIG. 3 is also described in relation to a substrate fabrication protocol, 400, as outlined in FIG. 4A. Various embodiments include more or less process parameters and/or stack layers. This more detailed description is provided for a more thorough understanding of the context of embodiments of the invention.

Referring to FIG. 3, photovoltaic stack 300 is a thin film stack including the following components: substrate, 305, a back contact layer, 310, an absorber layer, 315, a window layer, 320, a top contact layer, 325, and top encapsulation layer, 330. As described above, photovoltaic stacks can also have a back encapsulation layer, which in this example would be between substrate 305 and back contact 310. Back encapsulation can provide additional mechanical support and/or protection of the stack from outside contamination, for example, from moisture. In some embodiments, glass serves both as the back substrate and back encapsulation layer.

Starting with substrate 305, a back contact layer, 310 is applied to substrate 305, see 405. The substrate can be planar or a more complex geometry such as a cylinder or a rod. Back contact layer 310 is a thin film of material that provides one of the electrical contacts of the solar cell. In one embodiment, the back contact layer includes at least one of molybdenum, nickel, graphite, copper, tin and aluminum. The back contact can also be fabricated by laminating multiple layers for example using copper, graphite and a metal layer such as aluminum, tin and the like. This multiple layered back contact structure allows optimization of contact and series resistance. In one embodiment, the thickness of the back contact layer is between about 0.1 micron and about 10,000 microns, in another embodiment between about 0.1 microns and about 10 microns, in another embodiment between about 0.1 microns and about 1 micron.

Next, an absorber layer film, 315, is deposited, see 410. An absorber layer can be formed from, for example, CIGS, CdTe or amorphous silicon. In one embodiment, the absorber layer includes CdTe and/or is CdTe. In the embodiment described above, a process is performed that includes changing the grain structure of the absorber layer so as to optimize the properties of the absorber layer. Although the process for optimizing absorber layers may be described in terms of annealing, other processes that affect the grain structure of the absorber layer can alternatively be performed so as to optimize the absorber layer. In one embodiment, this includes annealing the absorber layer.

When the absorber layer is CdTe, annealing the CdTe layer includes heating at between about 250° C. and about 600° C. for between about 1 minute and about 60 minutes, in another embodiment between about 250° C. and about 450° C. for between about 1 minutes and about 30 minutes, in another embodiment between about 350° C. and about 450° C. for between about 10 minutes and about 20 minutes. In one embodiment, annealing the CdTe layer includes heating in the presence of cadmium chloride. The CdCl₂ can be dissolved in a solvent, for example an alcohol such as methanol, and spray applied to the surface of the CdTe. Annealing can be done under inert atmosphere or in air.

The processing of the absorber layer may also include converting the absorber layer to a p-type semiconductor and/or passivating the grain boundaries of the absorber layer and/or improving or establishing ohmic contact with the back contact layer. The thickness of the CdTe absorber layer depends on the semiconducting material, and is typically on the order of microns, varying from a few microns to tens of microns. In one embodiment, the thickness of the absorber layer is between about 0.5 micron and about 15 microns, in another embodiment between about 0.5 micron and about 5 microns, in another embodiment between about 0.5 microns and about 2 microns.

After processing the absorber layer for optimal properties, there may be void defects in the absorber layer. Defects in the absorber layer can include fissures or voids that may or may not span the entire thickness of the absorber layer, these defects are termed “voids” from herein. Whether or not a void spans the thickness of the absorber layer initially, it should be repaired because it may later cause a short due to breakdown of any remaining absorber material remaining between the contacts of the photovoltaic stack. That is, even if the void doesn't span the entire thickness of the absorber layer, if the void is not repaired there is more risk of eventual electrical shorts because there is less material between, for example, the back contact and the window layer. Methods described herein are employed to repair voids in the absorber layer prior to forming a window layer on the absorber layer. In certain embodiments, voids that do not span the entire thickness of the absorber layer are repaired along with voids that do pass through the absorber layer. Referring to FIG. 4A, the absorber layer is repaired, see 415. More details of methods for absorber layer repair are described below in relation to FIGS. 4B-6E.

Referring again to FIGS. 3 and 4A, after processing absorber layer 315 for optimal properties and repairing voids in the absorber layer, a window layer, 320, is deposited, see 420. The window layer is formed after deposition, optimization (e.g. affecting the grain structure and electrical properties of the absorber layer) and repair of the absorber layer. Window layer 320 is a film of semiconducting material that creates a p-n junction with absorber layer 315 and allows the maximum number of photons in the energy regime of interest to pass through to absorber layer 315. It is desirable to maintain nanostructures in the window layer for optimal properties, as described in U.S. patent application Ser. No. 12/764,812 (supra). In one embodiment, the window layer includes at least one of CdS, ZnSe (zinc selenide), ZnS (zinc sulphide), ZnO (zinc oxide), Cd(OH)SH (cadmium hydroxide sulphide), In(OH)SH (indium hydroxide sulphide), SnO₂ (tin (II) oxide) and Sn(O₂)S₂ (tin (IV) oxide sulphide). Window layer 320 can be an n- or p-type semiconductor, depending on the material used for the absorber layer. In one embodiment, the window layer is formed from a cadmium sulphide (CdS) which is an n-type semiconductor. Cadmium sulfide films are used, for example, in CdTe and CIGS thin film solar cells. In one embodiment, the thickness of the window layer is between about 50 Å and about 2000 Å, in another embodiment between about 50 Å and about 1000 Å, in another embodiment between about 50 Å and about 500 Å.

In one embodiment, the CdS film is nanostructured. Nanostructured CdS films can be produced, for example, via electrodeposition, wet chemical deposition, dry sputtering and the like. Nanostructured grain sizes make the grains behave as quantum structures. The quantum nature of the grains in the film increases the window layer's band gap, allowing a greater percentage of the incident radiation to pass through to the absorber layer, thereby increasing the efficiency of the solar cell. The thermal budget to which the window layer is subjected is carefully controlled so as to maintain the quantum nature of the grains and to take advantage of the increase in the band gap. In one embodiment, the window layer material includes a grain size of between about 5 Å and about 300 Å, in another embodiment between about 5 Å and about 50 Å, in another embodiment between about 5 Å and about 10 Å.

Referring again to FIGS. 3 and 4A, after the window layer is formed, a front contact layer, 325, is formed, see 425. Front (or top) contact layer 325 is a thin film of material that provides the other contact for photovoltaic stack 300. As described above, the top contact is made of a material that is transparent to the photons in the energy regime of interest for the ultimate solar cell. In one embodiment, the top contact layer includes at least one of indium tin oxide (ITO), aluminum doped zinc oxide, zinc oxide, fluorinated tin oxide, and/or a grid of metallic lines or a combination of transparent conductive oxide and a grid of metallic lines. The top contact layer thickness can be on the order of thousands of angstroms. In one embodiment, the thickness of the top contact layer is between about 500 Å and about 10,000 Å, in another embodiment between about 500 Å and about 5000 Å, in another embodiment between about 500 Å and about 3000 Å.

After the front contact layer is formed, an encapsulation layer, 330, is deposited, see 430. Encapsulation is used to provide environmental protection and/or further mechanical support to the cell. The top encapsulation is formed from a material that is highly transparent in the photon energy regime of interest. This top encapsulation layer can be formed from, for example, glass or other transparent material such as a polymeric material. In the event the encapsulation layer is not mechanically strong enough to provide support, a (front) suprastrate may optionally be applied, see 435. In one embodiment, the front contact and top encapsulation layers are applied in one step, for example, using a glass (the encapsulation layer and supportive superstrate) coated with a TCO (the front contact), where the TCO adjoins the window layer. In this embodiment, heating or other processing may be needed to ensure proper bonding and ohmic contact between the TCO and the window layer. In another embodiment, glass alone serves as an encapsulation layer (and front superstrate for mechanical support) that is applied over the front contact. After the encapsulation layer is applied, process flow 400 ends.

### D. Absorber Repair in Substrate Fabrication Methods

As described above, after processing an absorber layer for optimal properties, there may be void defects in the absorber layer. Certain methods described herein are employed to repair voids in the absorber layer prior to forming a window layer on the absorber layer, that is, when substrate fabrication is employed for making the photovoltaic stack.

As described above, by using substrate fabrication protocols, independent control of fabrication conditions for the back contact, absorber layer and window layer is achieved, for example, methods of improving the window layer's properties by decoupling the formation parameters of the window layer from those of the absorber layer and/or back contact layer, as mentioned above. There are other advantages to substrate fabrication, for example, substrate fabrication is well suited for fabrication on non-planar substrates. For example it is far easier to fabricate a photovoltaic stack on the convex surface of a cylindrical substrate, than to build a photovoltaic stack on a concave superstrate. Also, substrate fabrication makes the possibility of flexible solar cells more practicable. Substrate fabrication also can employ lower cost substrates than superstrates, for example, metal foils are cheaper than glass.

FIG. 4B is a process flow, 415, in accord with process flow 400 of FIG. 4A, that describes methods of repairing the absorber layer. First, an electrically insulating material is applied to the absorber layer in order to fill any voids in the absorber layer, see 440. In one embodiment, the electrically insulating material is added in a manner that fills the voids and also leaves some of the insulating material, typically but not necessarily a thin conformal film, on the field region of the absorber layer. In these embodiments, the excess insulating material is removed from the field region of the absorber layer, see 445. Once the voids are filled with the insulating material and any excess insulating material is removed from the field regions, the process flow is complete.

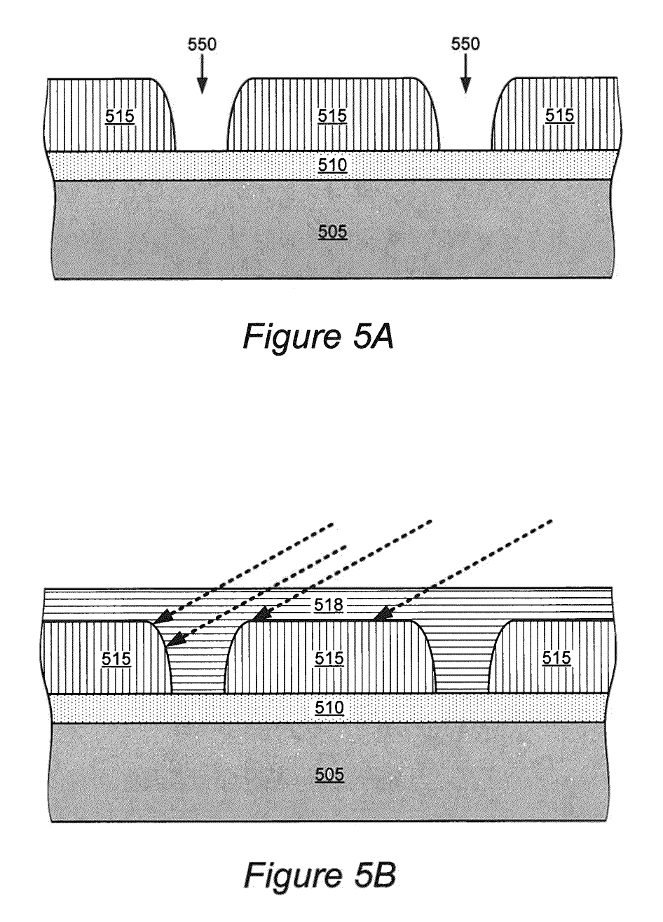

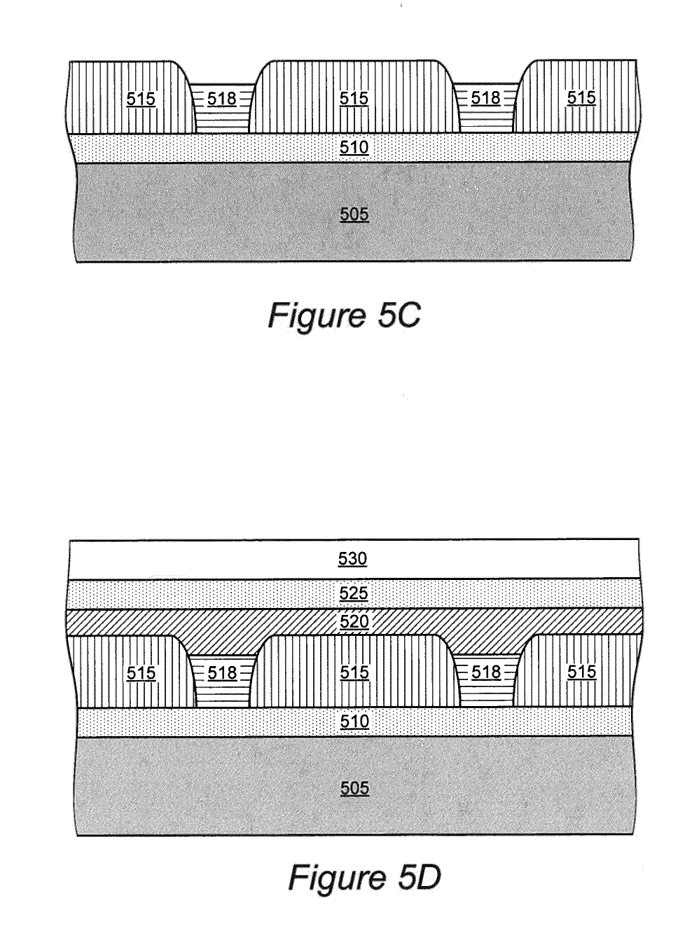

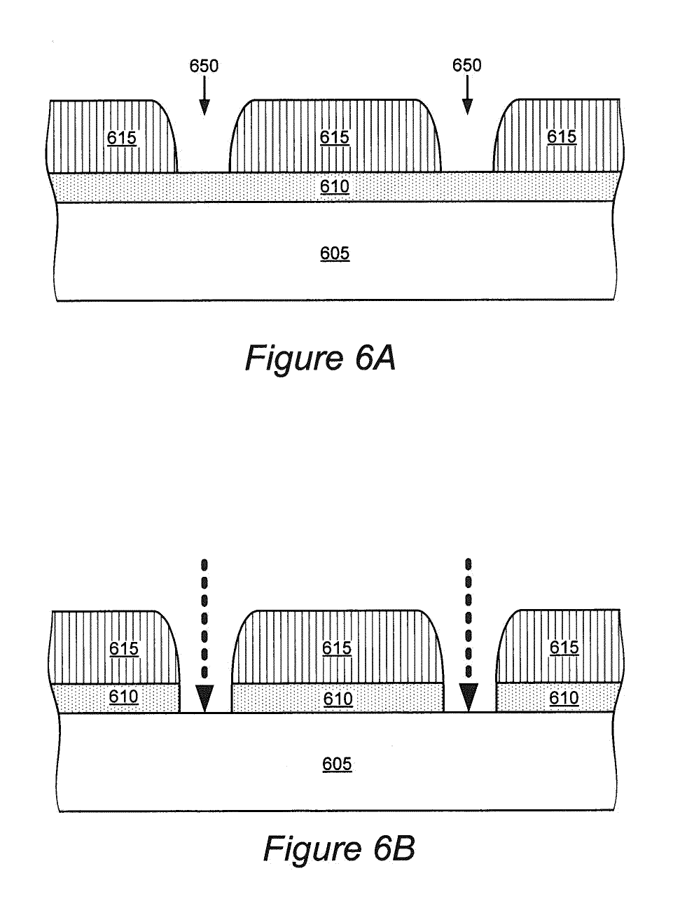

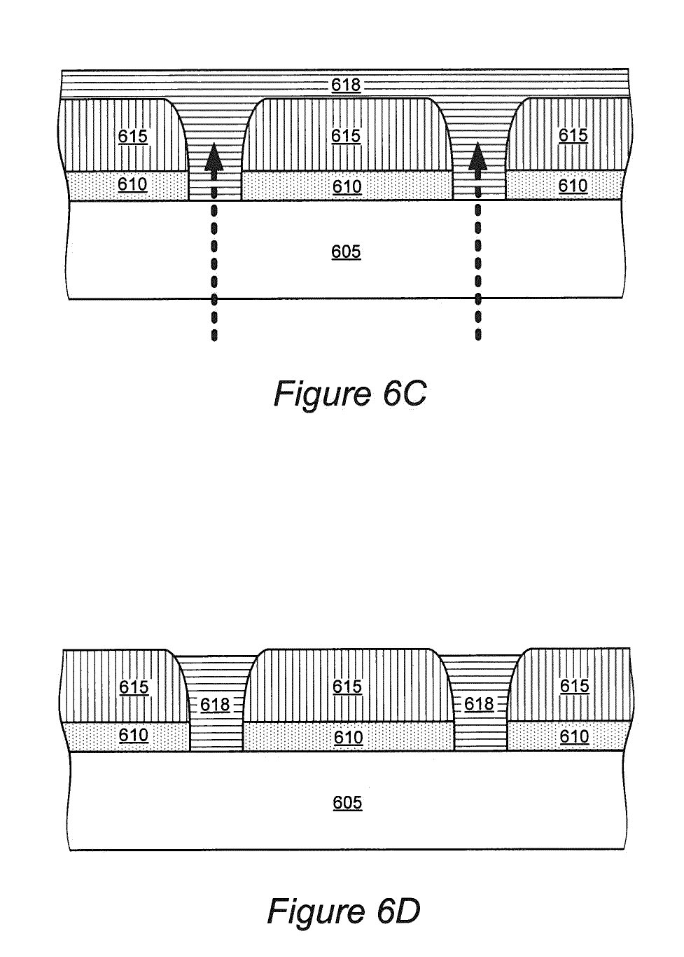

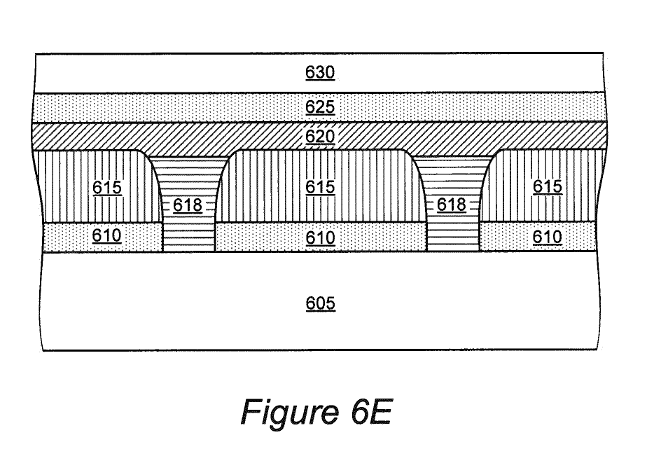

Thus, one embodiment is a method of fabricating a photovoltaic device, including: (a) forming an absorber layer on a back contact layer; (b) filling voids, at least partially, in the absorber layer with an electrically insulating material; and (c) forming a window layer on the absorber layer. In one embodiment, filling voids, at least partially, in the absorber layer with an electrically insulating material includes: (i) applying the electrically insulating material to the absorber layer to fill voids while leaving an excess of the electrically insulating material on the field region of the absorber layer; and (ii) removing the excess of the electrically insulating material from the field region of the absorber layer to expose the field region of the absorber layer while leaving at least some of the electrically insulating material in the voids. More specific embodiments are described below in relation to FIGS. 5A-5D and FIGS. 6A-6E. More particularly, methods described herein can vary depending on whether the back contact layer is formed on an opaque substrate or a transparent substrate.

For a frame of reference, absorber repair during superstrate fabrication protocols is briefly described below. Embodiments of the invention for absorber repair during substrate fabrication are described thereafter.

As described above in relation to FIG. 2, in the superstrate process, window layer 215 is first deposited on a superstrate, for example, a piece of float glass 205 with a TCO 210 as the top contact layer. After window layer 215 has been deposited, absorber layer 220 is deposited and subjected to various high temperature processing steps to improve the electrical performance of the material. As a result of the initial deposition and subsequent high temperature process steps, pinholes and/or cracks, that is, void defects, can develop in the absorber layer, some of which span the height of absorber layer 220. Prior to application of bottom contact 225, the missing material in absorber layer 220 is replaced by a low cost negative photoresist material by first depositing the photoresist on absorber layer 220, which may include baking at a low temperature, and exposing the photoresist using the proper wavelength of light. In this process, the light is shed from the superstrate (glass 205) side of the stack, which passes through superstrate 205, top contact (TCO) 210 and window layer 215. Because the material in absorber layer 220 absorbs the light in the regions where layer 220 is intact, only the photoresist in the voids of the absorber material is exposed to the light that passes through layers 205, 210 and 215. By incorporating a negative photoresist, the photoresist material can be left selectively in the voids after development, for example, in a solvent system that removes only the unexposed portions of the photoresist left on the field region of absorber layer 220. Thus, the voids in the absorber material are replaced by electrically insulating material that prevents direct contact of the back contact layer to the conductive window layer. As described above, void defects, if not replaced at least in part with electrically insulating material, would severely degrade the conversion efficiency of the photovoltaic device.

In a substrate fabrication scheme, there are obstacles, not present in superstrate fabrication, that must be overcome in order to fill voids in the absorber layer. For example, in superstrate absorber repair, the light used to expose the insulating material in the voids of the absorber layer is shone through the glass superstrate, adjoining TCO and window layer and thereby exposes only the photoresist in the voids. The remainder of the light is absorbed by the intact portions of absorber layer. Thus there are three substantially transparent layers through which the light can pass in order to expose the photoresist in the voids. In photovoltaic stacks, the bottom contact layer is typically not a transparent conductive oxide, but rather a metal or other opaque conductive material. Therefore, in a substrate fabrication scheme, there is an opaque intervening layer between the absorber layer and the substrate at the time the absorber layer is processed and voids need to be repaired. The opacity of the bottom contact must be addressed in substrate fabrication absorber repair. Also, often opaque substrates are used in photovoltaic devices, since opaque substrates are often cost effective and light need not pass through them in the finished photovoltaic stack. The inventors have developed methods which allow absorber layer repair in substrate fabrication protocols, where opaque back contacts are used in combination with either opaque or transparent substrates.

In one embodiment, where the back contact layer resides on an opaque substrate, applying the electrically insulating material to the absorber layer to fill voids while leaving an excess of the electrically insulating material on the field region of the absorber layer includes applying a negative photoresist to the absorber layer, exposing the negative photoresist via irradiation, for example on-axis illumination, of the exposed (top) surface of the photoresist. Removing any excess of the electrically insulating material from the field region of the absorber layer to expose the field region of the absorber layer while leaving at least some of the electrically insulating material in the voids includes etching back the fully exposed negative photoresist. In another embodiment, where the back contact layer resides on an opaque substrate, applying the electrically insulating material to the absorber layer to fill voids while leaving an excess of the electrically insulating material on the field region of the absorber layer includes applying a positive photoresist to the absorber layer, and exposing the positive photoresist to off-axis illumination on the exposed (top) surface of the photoresist in order to selectively expose the photoresist on the field and a portion of the photoresist in an upper region in the voids. Removing the excess of the electrically insulating material from the field region of the absorber layer to expose the field region of the absorber layer while leaving at least some of the electrically insulating material in the voids includes developing the positive photoresist in a developer that removes the exposed portions of the photoresist and/or etching back the photo resist. In one embodiment, the absorber layer is CIGS, CdTe or amorphous silicon. In a more specific embodiment, the absorber layer is CdTe. In one embodiment, the window layer includes at least one of CdS, ZnSe, ZnS, ZnO, Cd(OH)SH, In(OH)SH, SnO₂ and Sn(O₂)S₂. In a more specific embodiment, the window layer is CdS. In one embodiment, the CdS window layer is electrodeposited from a solution of cadmium chloride in DMSO.

It is important to note that in the opaque substrate/opaque back contact methods described herein, photoresists are not necessary. That is, since the methods employ processes articulated from a single side of the absorber layer, any suitable insulating material can be used. For example, if a non-photoresist insulating material is used, then an exposure step is not necessary. Etch back can be used in the same fashion as described herein on the insulating material without first having to expose the insulating material.

FIGS. 5A-5D are described in relation to absorber layer repair methods where an opaque substrate is used in substrate fabrication protocols. For convenience, these embodiments are described in terms of exemplary absorber layers, such as CdTe, but the invention is not limited to this absorber material.

Referring to FIG. 5A, an opaque substrate, for example a metal foil, 505, is applied an opaque back contact, 510, for example, a back contact made of molybdenum, nickel, graphite, copper, tin and/or aluminum. Absorber layer 515 is applied to back contact 510, and after processing as described above, absorber layer 515 contains void defects 550. In one embodiment, the absorber layer is CdTe. In this example, voids 550 are depicted as passing all the way through absorber layer 515, that is, back contact 510 is exposed at the bottom of each of voids 550.

Referring to FIG. 5B, and in accord with the methods described herein, an electrically insulating material, 518, for example a photoresist, is applied to absorber layer 515 in order to fill voids 550. As a result of a typical application process, for example spraying, spin coating, evaporation, drop casting, liquid dispense (for example employing ink jet technology), chemical deposition and the like, there is also some excess of electrically insulating material 518 left on the field region of absorber layer 515. In one embodiment, a negative photoresist is used, in another embodiment a positive photoresist is used.

The electrically insulating material has characteristics that produce effective gap filling into the voids as well as being well suited to planarization back to the field region level of the absorber layer. The electrically insulating material need not be a photoresist, that is, any material that has the above described characteristics and can be etched back to the field level of the absorber layer will work. Photoresists are particularly well suited for use as the electrically insulating material because they are commercially available in a wide variety of types, each tailored to particular process demands. For example there are positive photoresists and negative photoresists. A positive photoresist has the characteristic where only those portions of the photoresist that are exposed to light become soluble to a later applied photoresist developer. The portions of the positive photoresist that are unexposed remain insoluble to the photoresist developer. A negative photoresist has the opposite characteristic, that is, only those portions of the photoresist that are exposed to light become insoluble to the photoresist developer. The unexposed portions of the negative photoresist are dissolved by the photoresist developer. Additionally, photoresists are well characterized by, for example, electronic conductance or insulative properties, adhesion properties, cost, step coverage, wet chemical resistance, developer hydrophobicity or hydrophilicity, suitability to planarization, and the like.

Referring again to FIG. 5B, electrically insulating material 518 can be a positive, a negative photoresist or a non-photosensitive electrically insulating material. In this embodiment, after application, material 518 can be planarized, for example dry etched, back to the field region level, as depicted in FIG. 5C, without prior illumination. If material 518 is a photoresist, for example a negative photoresist, then, on-axis illumination is used to expose the entire portion of negative resist, both on the field and in the voids. Once exposed, the portion on the field is etched back. If material 518 is a positive photoresist, then, off-axis illumination can be employed, as depicted in FIG. 5B by the dotted arrows, to expose only those portions of material 518 on the field and in an upper portion of each of the voids 550. The low angle of the off-axis illumination exposes only the field and an upper portion of the positive resist in the voids. Upon development, the positive resist on the field region and in the upper region of each void is removed, leaving plugs of material 518 in the voids, as depicted in FIG. 5C. Alternatively, or additionally, the excess photoresist can be etched back as described above.

In methods described herein for repairing absorber void defects in these “opaque/opaque” substrate fabrication scenarios, void defects need not pass entirely through the absorber layer in order to be repaired because the methods include exposure from the absorber layer (top) side of the stack, rather than the substrate (bottom) side of the stack.

In one embodiment, the insulating material and/or the etch method is chosen such that during etch back, the electrically insulating material is removed at a faster rate than the absorber material. In this way, loss of absorber material is minimized. As a result of using differential etch back rates, when the absorber field level is reached the electrically insulating material in the voids is etched back below the absorber field region (for example as depicted in FIG. 5C). This is an example of a partially filled void. This result is acceptable because only a sufficient amount must remain in the voids to raise the contact resistance to a level where device performance is not impacted. Given that the absorber thickness is measured in micrometers and the insulator has a high resistivity, the thickness of the filling material can be, for example, one-tenth the thickness of the absorber layer, providing very substantial process margins.

In accord with opaque/opaque substrate fabrication absorber repair methods described above, one embodiment is a method of fabricating a photovoltaic device, including: (a) forming a CdTe layer on an opaque back contact layer supported by an opaque substrate; (b) applying a photoresist to the CdTe layer such that a plurality of void defects are at least partially filled; and (c) removing any excess of the photoresist from the field region of the CdTe layer and an upper region from each of the plurality of void defects. In one embodiment the photoresist is a positive resist, (b) includes exposing the positive photoresist to off-axis illumination and (c) includes developing the positive photoresist. In another embodiment, the photoresist is a negative resist, (b) includes exposing the negative photoresist to on-axis illumination and (c) includes etching back the negative photoresist.

Referring to FIG. 5D, after absorber layer 515 is repaired, a window layer, 520, is formed on the repaired absorber layer. Window layer 520 can include materials as described above. Methods of the invention further include forming at least a front contact layer over the window layer and encapsulating the photovoltaic stack so as to form a solar cell module. In this example, top contact 525 and encapsulation layer 530 are deposited on window layer 520. In one embodiment, the front contact layer and encapsulation are applied together as, for example, a glass superstrate (encapsulation) with a TCO (front contact).

As described above, the inventors have also developed methods which allow absorber layer repair in substrate fabrication protocols, where transparent substrates are used in combination with opaque back contacts. For the purposes of this description, transparent substrates are described as “substantially transparent” because most materials have some intrinsic level of light absorption. Thus “transparent” and “substantially transparent” are used interchangeably.

In one embodiment, where the back contact layer resides on substantially transparent substrate, methods further include selectively etching through the back contact layer via the voids in the absorber layer, such that the voids are extended through the absorber layer, through the back contact layer until the substantially transparent substrate is exposed at the bottom of the voids. This is done prior to applying the electrically insulating material to the absorber layer to fill voids while leaving an excess of the electrically insulating material on the field region of the absorber layer. Applying the electrically insulating material to the absorber layer to fill voids while leaving an excess of the electrically insulating material on the field region of the absorber layer includes applying a negative photoresist to the absorber layer and selectively exposing the photoresist in the voids via irradiative exposure through the substantially transparent substrate. Removing the excess of the electrically insulating material from the field region of the absorber layer to expose the field region of the absorber layer while leaving at least some of the electrically insulating material in the voids includes developing the photoresist in a developer that removes the unexposed portions of the negative photoresist and/or etching back the photoresist. In one embodiment, the absorber layer is CIGS, CdTe or amorphous silicon. In a more specific embodiment, the absorber layer is CdTe. In one embodiment, the window layer includes at least one of CdS, ZnSe, ZnS, ZnO, Cd(OH)SH, In(OH)SH, SnO₂ and Sn(O₂)S₂. In a more specific embodiment, the window layer is CdS. In one embodiment, the CdS window layer is electrodeposited from a solution of cadmium chloride in DMSO.

FIGS. 6A-6E are described in relation to absorber layer repair methods where a substantially transparent substrate and an opaque back contact are used in substrate fabrication protocols. Again, for convenience, these embodiments are described in terms of exemplary absorber layers, such as CdTe, but the invention is not limited to this absorber material. In these methods, the absorber material is used as a shadow mask through which the back contact layer is etched, via the voids in the absorber layer. That is, the voids are used as conduits for the etchant such that the voids are extended through the back contact layer to expose the transparent substrate at the bottom of the void. This creates a light transmissive path to the voids via the substantially transparent substrate side of the stack.

Referring to FIG. 6A, a transparent substrate, for example a glass, 605, is applied an opaque back contact, 610, for example, a back contact made of molybdenum, nickel, graphite, copper, tin and/or aluminum. Absorber layer 615 is applied to back contact 610, and after processing as described above, absorber layer 615 contains void defects 650. In one embodiment, the absorber layer is CdTe. In this example, voids 650 are depicted as passing all the way through absorber layer 615, that is, back contact 610 is exposed at the bottom of each of voids 650. In methods described herein for repairing absorber void defects in this “transparent/opaque” substrate fabrication scenario, void defects, along with the intact absorber material, are used as a mask for selectively etching through back contact 610 where the voids reside, thus extending the voids down to the transparent substrate.

Referring to FIG. 6B, and in accord with the methods described herein, when absorber layer 615 is used as a mask for etching, voids 650 are extended through back contact 610 until transparent substrate 605 is reached, as indicated by the dashed arrows. The etch can be conducted by wet chemicals, dry plasmas or both. Referring to FIG. 6C, after the voids are etched to substrate 605, electrically insulating material, 618, is deposited so as to fill the voids. Typically, excess of material 618 remains on the field region of absorber layer 615 as a result of the deposition process, for example, those described above in relation to FIG. 5B. The electrically insulating material can be any as described above. For example, in one embodiment, a positive resist is used along with off-axis illumination as with the opaque/opaque method.

In one embodiment, a negative photoresist is used because it can be exposed selectively in the voids via exposure from the substrate side of the device stack, as indicated by the dashed arrows in FIG. 6C. That is, since back contact 610 is opaque, it acts as a mask when the stack is illuminated from the substrate side, that is, through transparent substrate 605. When material 618 is a negative resist, selective exposure to the resist only in the voids allows selective removal of the excess resist on the absorber field region, for example, using a standard developer for a negative resist. Once the electrically insulating material is removed from the field region, as depicted in FIG. 6D, the voids remain at least partially filled with material 618.

In one embodiment, where a photoresist in the voids is exposed to irradiation, for example light, only enough exposure is provided to expose a lower portion of the material in the void, that is proximate to substrate 605. In this way, when developed, there is less chance of exposed resist plugs standing above the absorber field region level after development. That is, the developer may remove some unexposed resist material from the aperture region of the voids, but not all the resist, leaving at least some resist in the voids. As described above, this result is acceptable because only a sufficient amount must remain in the voids to raise the contact resistance to a level where device performance is not impacted. Again, process margins benefit from this method because more strongly solvating developers may be used and/or less careful stringency can be applied to development time because there is no need to necessarily prevent partial resist removal from the voids.

In another embodiment, the photoresist is exposed such that, after development, there are plugs of exposed photoresist above the field region of the absorber layer. This does not seem to negatively impact the device, and is another way of obtaining high process margins. So long as the absorber layer field is exposed, it is acceptable if the insulating material in the voids is above, at or below the absorber field region.

As described above in relation to opaque/opaque substrate fabrication absorber repair, etch back can also be employed in transparent/opaque substrate fabrication absorber repair to remove excess insulator from the field region. In one embodiment, differential etch rates are employed, where the electrically insulating material is removed at a faster rate than the absorber material. In this way, loss of absorber material is minimized. As a result of using differential etch back rates, when the absorber field level is reached the electrically insulating material in the voids is etched back below the absorber field region (for example as depicted in FIG. 6D). This is acceptable for the reasons described above in relation to FIG. 5C.

In accord with transparent/opaque substrate fabrication absorber repair methods described above, one embodiment is a method of fabricating a photovoltaic device, including: (a) forming a CdTe layer on an opaque back contact layer supported by a substantially transparent substrate; (b) etching through the opaque back contact layer via a plurality of void defects in the CdTe layer to reach the substantially transparent substrate; (c) applying a negative photoresist to the CdTe layer; (d) selectively exposing the negative photoresist in the voids by illuminating the substantially transparent substrate; and (e) removing excess of the negative photoresist from the field region of the CdTe layer; where the negative photoresist is electrically insulating at least upon exposure.

The advantages of transparent/opaque substrate fabrication absorber repair methods described herein are simplicity and compatibility with existing processes and equipment used in superstrate fabrication. The process margins are also high, yielding a robust manufacturing sequence.

Referring to FIG. 6E, after absorber layer 615 is repaired, a window layer, 620, is formed on the repaired absorber layer. Window layer 620 can include materials as described above. Methods of the invention further include forming at least a front contact layer over the window layer and encapsulating the photovoltaic stack so as to form a solar cell module. In this example, top contact 625 and encapsulation layer 630 are deposited on window layer 620. In one embodiment, the front contact layer and encapsulation are applied together as, for example, a glass superstrate (encapsulation) with a TCO (front contact).

Methods described herein are exemplified as being carried out on substantially flat substrates, such as conventional glass substrates. However, methods described herein can also be employed substrates with non-planar geometries, such as cylinders, curved and/or irregular contoured surfaces, depending on the desired configuration of the final product photovoltaic device. One embodiment is any method described herein wherein the substrate comprises a curved architecture, for example a cylinder, a parabola, a cone, a hemisphere, and the like. The curved architecture can be convex, concave or have both components, depending upon the need.

Although the foregoing invention has been described in some detail for purposes of clarity of understanding, it will be apparent that certain changes and modifications may be practiced within the scope of the appended claims. Therefore, the present embodiments are to be considered as illustrative and not restrictive and the invention is not to be limited to the details given herein, but may be modified within the scope and equivalents of the appended claims.

What is claimed is:

1. A method of fabricating a photovoltaic device, comprising:
(a) forming an absorber layer on a back contact layer;
(b) filling voids, at least partially, in the absorber layer with an electrically insulating material; and
(c) forming a window layer on the absorber layer.

2. The method of claim 1, wherein (b) comprises:
(i) applying the electrically insulating material to the absorber layer to fill voids; and
(ii) removing any excess of the electrically insulating material from the field region of the absorber layer to expose the field region of the absorber layer while leaving at least some of the electrically insulating material in the voids.

3. The method of claim 2, wherein the back contact layer resides on an opaque substrate.

4. The method of claim 3, wherein (i) comprises applying a negative photoresist to the absorber layer, exposing the negative photoresist via on-axis exposure of the exposed surface of the negative photoresist and (ii) comprises etching back the negative photoresist; or (i) comprises applying a positive photoresist to the absorber layer, exposing the photoresist to off-axis illumination on the exposed surface of the positive photoresist in order to selectively expose the positive photoresist on the field region of the absorber layer and in an upper region of each of the voids, and (ii) comprises developing the photoresist in a developer that removes the exposed portions of the positive photoresist and/or etching back the positive photo resist.

5. The method of claim 4, wherein (i) comprises applying a positive photoresist to the absorber layer, exposing the photoresist to off-axis illumination on the exposed surface of the positive photoresist in order to selectively expose the positive photoresist on the field region of the absorber layer and in an upper region of each of the voids, and (ii) comprises developing the photoresist in a developer that removes the exposed portions of the positive photoresist and/or etching back the positive photo resist.

6. The method of claim 5, wherein the absorber layer is CIGS, CdTe or amorphous silicon.

7. The method of claim 6, wherein the absorber layer is CdTe.

8. The method of claim 7, wherein the window layer comprises at least one of CdS, ZnSe, ZnS, ZnO, Cd(OH)SH, In(OH)SH, SnO₂ and Sn(0₂)S₂.

9. The method of claim 8, wherein the window layer is CdS.

10. The method of claim 9, wherein the CdS is electrodeposited from a solution of cadmium chloride in DMSO.

11. The method of claim 9, further comprising:
(iv) forming a front contact layer over the window layer; and
(v) encapsulating the photovoltaic stack.

12. The method of claim 8, wherein the back contact comprises at least one of molybdenum, nickel, graphite, copper, tin and aluminum.

13. The method of claim 12, wherein the back contact comprises at least one of copper and nickel.

14. The method of claim 2, wherein the back contact layer resides on a substantially transparent substrate.

15. The method of claim 14, further comprising, prior to (i), selectively etching through the back contact layer via the voids in the absorber layer, such that the voids are extended through the absorber layer, through the back contact layer, and until the substantially transparent substrate is exposed at the bottom of the voids.

16. The method of claim 15, wherein (i) comprises applying a negative photoresist to the absorber layer and selectively exposing the negative photoresist in the voids via irradiative exposure through the substantially transparent substrate, and (ii) comprises developing the negative photoresist in a developer that removes the unexposed portions of the photoresist and/or etching back the photoresist.

17. The method of claim 16, wherein the absorber layer is CIGS, CdTe or amorphous silicon.

18. The method of claim 17, wherein the absorber layer is CdTe.

19. The method of claim 18, wherein the window layer comprises at least one of CdS, ZnSe, ZnS, ZnO, Cd(OH)SH, In(OH)SH, SnO₂ and Sn(O₂)S₂.

20. The method of claim 19, wherein the window layer is CdS.

21. The method of claim 20, wherein the CdS is electrodeposited from a solution of cadmium chloride in DMSO.

22. The method of claim 20, further comprising:
(iv) forming a front contact layer over the window layer; and
(v) encapsulating the photovoltaic stack.

23. The method of claim 20, wherein the back contact comprises at least one of molybdenum, nickel, graphite, copper, tin and aluminum.

24. The method of claim 23, wherein the back contact comprises at least one of copper and nickel.

25. The method of claim 9, wherein the opaque substrate is curved.

26. The method of claim 20, wherein the substantially transparent substrate is curved.
